(19) United States
(12) Patent Application Publication
(10) Pub. No.: US 2025/0140644 A1
(43) Pub. Date: May 1, 2025

(54) HEAT DISSIPATION BY NANO PIPES

(71) Applicant: Taiwan Semiconductor Manufacturing Company, Ltd., Hsinchu (TW)

(72) Inventors: Ming-Hsien Lin, Hsinchu County (TW); Wen-Che Liao, New Taipei City (TW); Kun-Yen Liao, Taipei City (TW); Hsiao-Kang Chang, Hsinchu City (TW)

(21) Appl. No.: 18/422,392

(22) Filed: Jan. 25, 2024

Related U.S. Application Data
(60) Provisional application No. 63/593,771, filed on Oct. 27, 2023.

(51) Int. Cl. H01L 23/427; H01L 21/02; H01L 21/768; H01L 23/373

(52) U.S. Cl. CPC H01L 23/427; H01L 21/02282; H01L 21/76819; H01L 21/76828; H01L 21/76829; H01L 23/3732

(57) ABSTRACT

A contact structure according to the present disclosure includes a conductive feature, an etch stop layer (ESL) over the conductive feature, a dielectric layer over the ESL, and a contact feature extending through the dielectric layer and the ESL to contact the conductive feature. The dielectric layer includes a low-k dielectric matrix material, and nano-pipes disposed in the low-k dielectric matrix material and configured to reduce a thermal resistance of the dielectric layer.

### PRIORITY DATA

The present application claims the benefit of U.S. Provisional Application No. 63/593,771, filed Oct. 27, 2023, the entirety of which is herein incorporated by reference.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

As device dimensions continue to shrink, performance of back-end-of-line (BEOL) interconnect structures are subject to higher requirements. Low dielectric constant (low-k) materials have been incorporated into interconnect structures to lower capacitance. While the low-k materials serve their purposes of lowering capacitance, their lackluster thermal conductivities present challenges in dissipation of heat from front-end-of-line (FEOL) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart of a method 100 for forming a contact structure through a dielectric layer, according to one or more aspects of the present disclosure.

FIGS. 2-9 are fragmentary cross-sectional views of a workpiece at various stages of fabrication according to the method in FIG. 1, according to one or more aspects of the present disclosure.

FIG. 10 is a flowchart of a method 300 for forming a contact structure through a dielectric layer, according to one or more aspects of the present disclosure.

FIGS. 11-19 are fragmentary cross-sectional views of a workpiece at various stages of fabrication according to the method in FIG. 10, according to one or more aspects of the present disclosure.

FIG. 20 is a flowchart of a method 400 for forming a contact structure through a dielectric layer, according to one or more aspects of the present disclosure.

FIGS. 21-29 are fragmentary cross-sectional views of a workpiece at various stages of fabrication according to the method in FIG. 20, according to one or more aspects of the present disclosure.

FIG. 30 includes a chart showing how presence of nano-pipes in a low-k dielectric base material can reduce thermal resistance in a simulation, according to one or more aspects of the present disclosure

FIGS. 31 and 32 provide schematic cross-sectional views of an interconnect structure that includes low-k dielectric layers with embedded nano-pipes, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Source/drain region(s) may refer to a source or a drain, individually or collectively, dependent upon the context.

As the front-end-of-line (FEOL) devices becomes smaller, the back-end-of-line (BEOL) interconnect structures play a greater role in keeping up with the power, performance and area requirements. The BEOL interconnect structures may include low-k dielectric material to keep the parasitic capacitance down. In general, low-k dielectric materials possess thermal conductivities lower than those of high-k dielectric materials, metals or semiconductor materials. For example, a thermal conductivity of silicon oxide is two orders of magnitude lower than that of silicon. The low thermal conductivities of low-k dielectric materials prevent them from effectively dissipating heat generated by the FEOL devices. When it comes to dielectric materials in the BEOL interconnect structures, the industry scrambles to find a solution to achieve high thermal conductivity while keeping a low parasitic capacitance.

The present disclosure provides methods to increase thermal conductivity of a low-k dielectric layer in a contact structure. In an example process, a mixture of a low-k dielectric precursor solution and high thermal conductivity nanoparticles is deposited over an etch stop layer (ESL). A thermal treatment or a combination of the thermal treatment and an electromagnetic field are applied to the mixture to cause self-aggregation of the high thermal conductivity nanoparticles to form high thermal conductivity nano-pipes. The mixture is then cured to form a low-k dielectric layer. In another example process, a low-k dielectric precursor is deposited over the ESL. Nanoparticles or pre-formed nano-pipes are injected into the deposited low-k dielectric precursor. After the injection, the low-k dielectric precursor is cured to form the low-k dielectric layer. In yet another example process, low-k dielectric layers and the high thermal conductivity layers are deposited and cured alternating to form a multilayer structure. The multilayer structure includes a low dielectric constant but a relatively high thermal conductivity for effective thermal dissipation.

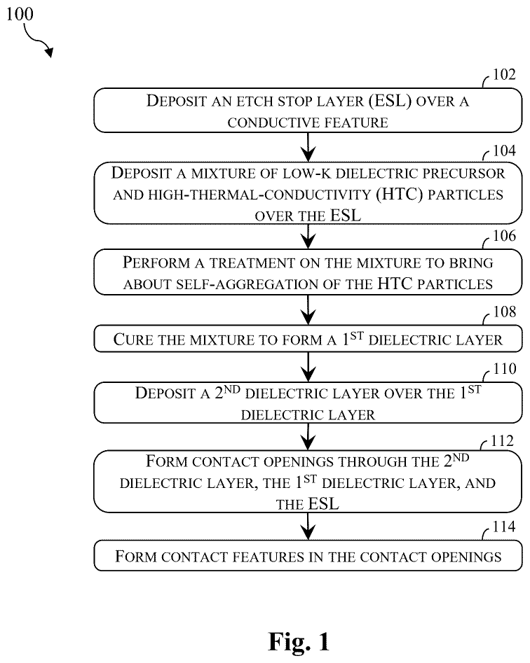

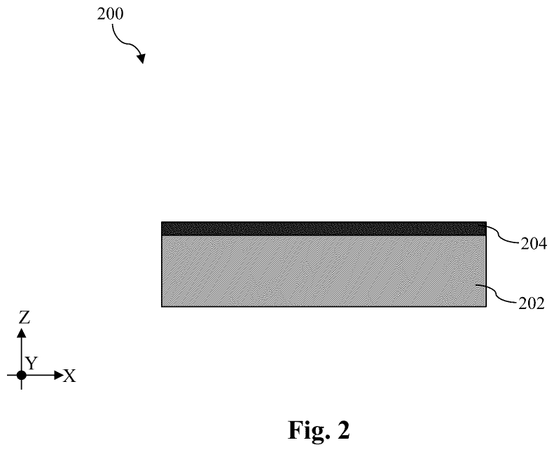

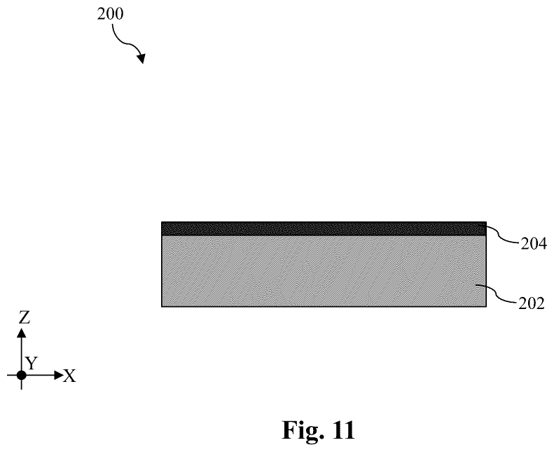

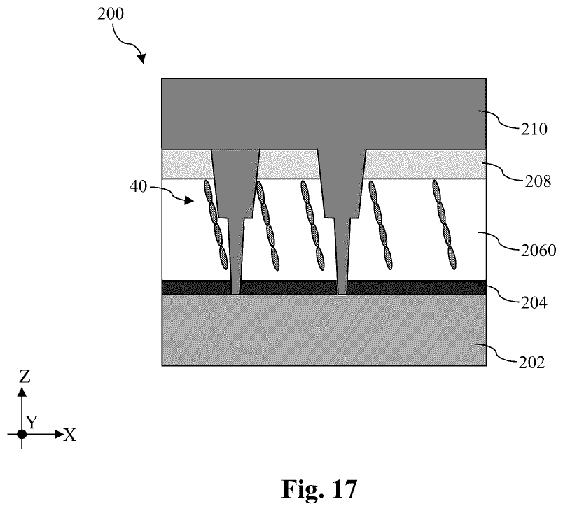

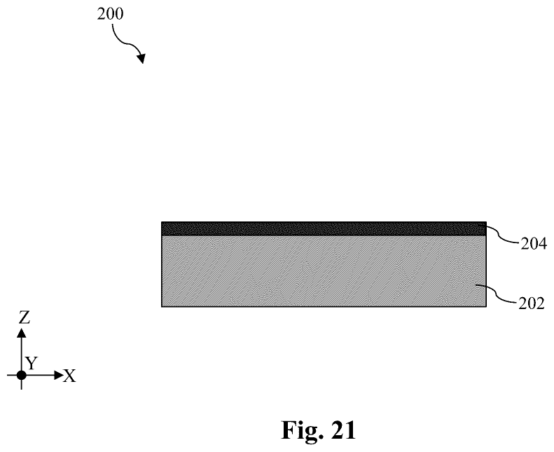

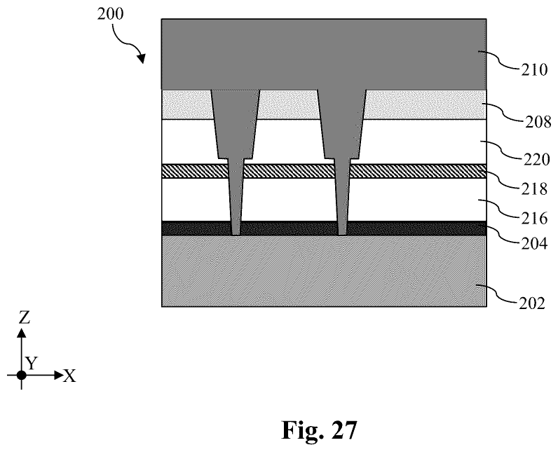

The various aspects of the present disclosure will now be described in more detail with reference to the figures. In that regard, FIGS. 1, 10 and 18 are flowcharts illustrating methods 100, 300 and 400 for forming a contact structure on a workpiece 200. Methods 100, 300 and 400 are merely examples and are not intended to limit the present disclosure to what is explicitly illustrated in method 100, 300 or 400. Additional steps may be provided before, during and after method 100, 300 or 400, and some steps described can be replaced, eliminated, or moved around for additional embodiments. Not all steps are described herein in detail for reasons of simplicity. Method 100 is described below in conjunction with FIGS. 2-9, which are fragmentary cross-sectional views of a workpiece 200 at different stages of fabrication according to embodiments of method 100. Method 300 is described below in conjunction with FIGS. 11-19, which are fragmentary cross-sectional views of a workpiece 200 at different stages of fabrication according to embodiments of method 300. Method 400 is described below in conjunction with FIGS. 21-29, which are fragmentary cross-sectional views of a workpiece 200 at different stages of fabrication according to embodiments of method 400. Because the workpiece 200 will be fabricated into a semiconductor structure 200 upon conclusion of the fabrication processes, the workpiece 200 may be referred to as a semiconductor structure 200 as the context requires. Additionally, throughout the present application and across different embodiments, like reference numerals denote like features with similar structures and compositions, unless otherwise excepted.

Referring to FIGS. 1 and 2, method 100 includes a block 102 where an etch stop layer (ESL) 204 is deposited over a conductive feature 202. In the depicted embodiment, the conductive feature 202 may be a metal line in a back-end-of-line (BEOL) interconnect structure. In some other embodiments not explicitly shown in FIG. 2, the conductive feature 202 may be a contact via or a dual-damascene feature that includes a metal line and a contact via. The conductive feature 202 may include copper (Cu), nickel (Ni), cobalt (Co), aluminum (Al), or a combination thereof. In one embodiment, the conductive feature 202 includes copper (Cu). The ESL 204 may include nitrogen-doped silicon carbide (SiC: N or silicon carbonitride), aluminum nitride (AlN), aluminum oxide (AlO), silicon nitride, oxygen-doped silicon carbide (SiC: O or silicon oxycarbide), or a combination thereof. In one embodiment, the ESL 204 includes nitrogen-doped silicon carbide. In some implementations, the ESL 204 may be deposited using atomic layer deposition (ALD), chemical vapor deposition (CVD), or physical vapor deposition (PVD). The conductive feature 202, the ESL 204 and further structures to be fabricated over the ESL may be collectively referred to as a workpiece 200.

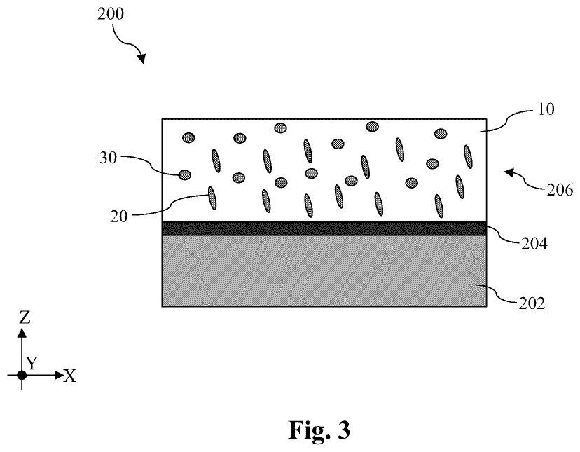

Referring to FIGS. 1 and 3, method 100 include a block 104 where a mixture 206 of a low-k dielectric precursor 10 and high thermal conductivity particles is deposited over the ESL 204. Here, the mixture 206 may be a solution, a slurry, a suspension, or a sol-gel because the present disclosure envisions all reasonable mixture of a low-k component and a high thermal conductivity component. The mixture 206 includes a low-k dielectric precursor 10 and at least one species of high thermal conductivity particles. In the depicted embodiment, the at least one species of high thermal conductivity particles include one-dimensional (1D) nano-particles 20 and two-dimensional (2D) nano-particles 30. An example of the ID nano-particles 20 is graphene or carbon nanotubes (CNTs). An example of the 2D nano-particles 30 is boron nitride (BN). Other examples of the high thermal conductivity particles may include diamond, silicon carbide (SiC), beryllium oxide (BeO), boron phosphide (BP), aluminum nitride (AlN), beryllium sulfide (BeS), boron arsenide (BAs), gallium nitride (GaN), aluminum phosphide (AIP), gallium phosphide (GaP), or aluminum oxide (Al₂O₃). In some embodiments, in order to facilitate subsequent self-aggregation, the high thermal conductivity particles may be chemically treated to carry a positive charge or a negative charge. For example, boron nitride nano-particles may be chemically treated to be positively charged and carbon nano tubes may be chemically treated to carry a negative charge. In some embodiments, the mixture 206 may include only one species of the high thermal conductivity particles. For example, the mixture 206 may include only 1D nano-particles 20 or only 2D nano-particles 30.

The low-k dielectric precursor 10 may include silicon (Si), carbon (C), oxygen (O), and hydrogen (H) and is suitable for spin-on coating or flowable chemical vapor deposition (FCVD). In some embodiments, the low-k dielectric precursor 10 may include hydrogen-silsesquioxane (HSSQ), methyl-silsesquioxane (MSSQ), or carbon-doped silicon oxide (i.e., silicon-doped silica glass). In order for the subsequent self-aggregation to take place, the mixture 206 is fluidic or flowable as deposited at block 104. The fluidity or flowability of the mixture 206 allows the at least one species of the high thermal conductivity particles to move around or orient themselves in the mixture 206 in response to dipole-dipole forces, electric fields, magnetic fields, or electrostatic attractions. In some instances, the mixture 206 may further include a solvent and surfactants. Example solvents may include di-methylformamide (DMF), tetra-hydrofuran (THF), n-butyl acetate (nBA), or n-methyl-2-pyrrolidone (NMP). The surfactants help the at least one species of high thermal conductivity particles to disperse in the mixture 206 without agglomeration. At block 104, the mixture 206 may be deposited over the ESL 204 by spin-on coating or flowable CVD (FCVD).

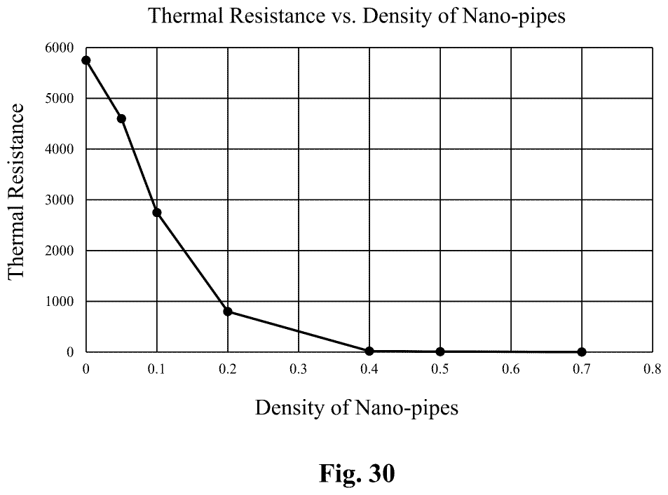

In order to keep a low dielectric constant and to prevent agglomeration due to high particle loading, a volumetric percentage of the at least one species of high thermal conductivity particles in the mixture 206 may be between 10% and about 25%. When the volumetric percentage is below 10%, amount of at least one species of high thermal conductivity particles may not be sufficient to form heat conduction paths. When the volumetric percentage is greater than 25%, amount of at least one species of high thermal conductivity particles may increase a dielectric constant of the dielectric layer formed from the mixture 206. The volumetric percentage of the high thermal conductivity particles correlates to a density of nano-pipes formed from the high thermal conductivity particles. FIG. 30 includes a chart illustrating how presence of nano-pipes in a low-k dielectric base material can reduce thermal resistance in a simulation. The simulation results indicates that a thermal conductivity may be reduced in half when a density of the nano-pipes in the low-k base material is about 10%. While additional nano-pipes has the effect of reducing thermal resistance, the effect becomes less significant after the density of the nano-pipes reaches about 40%.

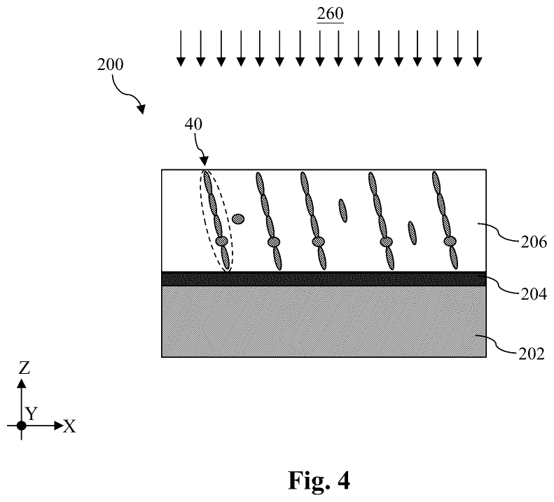

Referring to FIGS. 1, 4 and 5, method 100 includes a block 106 where a treatment is performed on the mixture 206 to bring about self-aggregation of the high thermal conductivity particles in the mixture 206. In some embodiments represented in FIG. 4, the treatment at block 106 may include a thermal treatment 260, such as an anneal process. The thermal treatment 260 is intended to provide energy to the at least one species of high thermal conductivity particles in the mixture 206 without curing the mixture 206 or causing substantial solvent evaporation. For that reasons, a process temperature of the thermal treatment 260 is lower than an anneal temperature of an anneal process to cure the mixture 206. In some implementations, a process temperature of the thermal treatment 260 may be between about 80° C. and about 180° C.

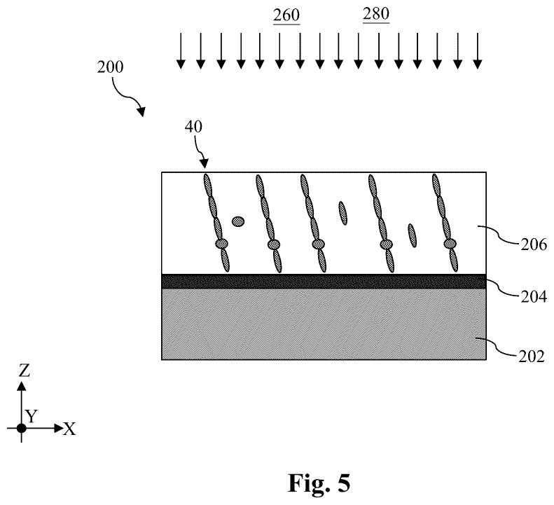

In some other embodiments illustrated in FIG. 5, the treatment at block 106 includes both the thermal treatment 260 and an electromagnetic field 280. In these embodiments shown in FIG. 5, the thermal treatment 260 provide energy to the at least one species of high thermal conductivity particles to have Brownian motion and rotate in the mixture 206 while the electromagnetic field 280 provides additional driving force to at least one species of high thermal conductivity particles to have an aligned self-aggregation. Depending on the functional groups on the at least one species of high thermal conductivity particles, the electromagnetic field 280 may be an electric field, a magnetic field, or both. In some embodiments, when the at least one high thermal conductivity particles include ceramic materials, such as beryllium oxide (BeO), aluminum oxide (Al₂O₃), the thermal treatment 260 and the electromagnetic field 280 may cause the high thermal conductivity particles to form chemically bonded boundaries, which may form nano-pipes or heat conduction networks in the mixture 206.

As shown in FIGS. 4 and 5, the treatment at block 106 may cause at least some of the high thermal conductivity particles to self-aggregate in response to Van der Waals forces, chemical bonding, dipole moment, or electrostatic force. As a result, nano-pipes 40 may form. In some embodiments, the nano-pipes 40 may include the 1D nano-particles 20, the 2D nano-particles 30, or a combination thereof. For example, when the 1D nano-particles 20 include negatively charged carbon nanotubes and the 2D nano-particles 30 include positively charged boron nitride (BN), a mixture of the thermal treatment 260 and an electric field (i.e., a form of the electromagnetic field 280) may cause 1D nano-particles 20 and the 2D nano-particles 30 to attract to one another by electrostatic force and align with the electric field. When a direction of the electric field is perpendicular (i.e., normal) to a top surface of the conductive feature 202 along the Z direction, the nano-pipes 40 may be aligned lengthwise along the Z direction. Because nano-particles in the nano-pipes 40 have high thermal conductivity, the nano-pipes 40 provide high thermal conductivity heat conduction paths in the deposited mixture 206. When the nano-pipes 40 are aligned lengthwise, they provide directional high thermal conductivity heat conduction paths.

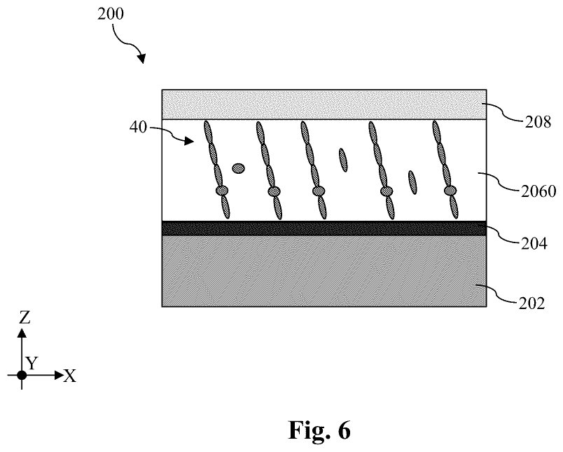

Referring to FIGS. 1 and 6, method 100 includes a block 108 where the mixture 206 is cured to form a first dielectric layer 2060. The first dielectric layer 2060 includes silicon (Si), carbon (C), oxygen (O), and hydrogen (H). In one embodiment, the first dielectric layer 2060 may include carbon-doped silica glass (SiCOH). In some embodiments, the curing of the mixture 206 at block 108 may include an anneal process or a ultraviolet (UV) curing process. Generally, the anneal process or the UV curing process may evaporate solvent in the mixture 206 or causing a reduction reaction in the mixture 206 to form the first dielectric layer 2060. Because the mixture 206 includes the low-k dielectric precursor 10, the first dielectric layer 2060 may still have low dielectric constant and may be referred to as a low-k dielectric layer 2060. As a whole, the first dielectric layer 2060 may be considered a low-k dielectric matrix with high thermal conductivity nano-pipes 40 embedded therein. The low-k dielectric matrix keeps the overall dielectric constant of the first dielectric layer 2060 low while the high thermal conductivity nano-pipes 40 provide high thermal conductivity channels for heat dissipation. When the curing at block 108 include an anneal process, an anneal temperature of the anneal process is greater than the process temperature of the thermal treatment 260 at block 106.

Referring to FIGS. 1 and 6, method 100 includes a block 110 where a second dielectric layer 208 is deposited over the first dielectric layer 2060. The second dielectric layer 208 functions at a hard mask during the subsequent formation of contact openings through the first dielectric layer 2060 and the ESL 204. To serve its purposes, the second dielectric layer 208 has a greater density and structural integrity than the first dielectric layer 2060. In some embodiments, the second dielectric layer 208 may include tetraethylorthosilicate (TEOS) oxide, un-doped silicate glass, borophosphosilicate glass (BPSG), fluorosilicate glass (FSG), phosphosilicate glass (PSG), fluorine-doped silicon dioxide, silicon oxide, or combinations thereof. In one embodiment, the second dielectric layer 208 includes silicon oxide. In some embodiments, the second dielectric layer 208 may be deposited using spin-on coating, CVD, atmospheric pressure CVD (APCVD), or FCVD.

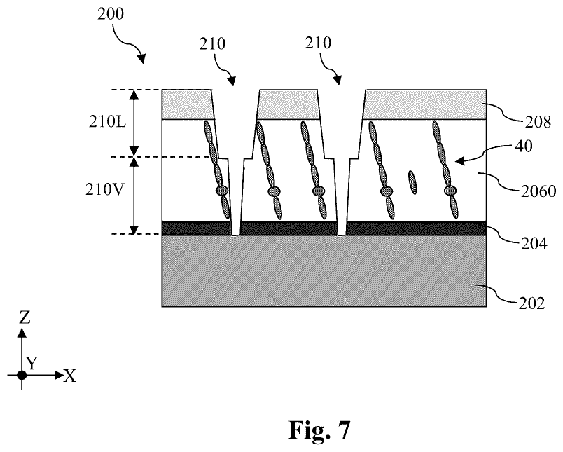

Referring to FIGS. 1 and 7, method 100 includes a block 112 where contact openings 210 are formed through the second dielectric layer 208, the first dielectric layer 2060, and the ESL 204. In an example process, a patterned mask is first formed by photolithography processes and a dry etch process is performed to form a via opening through the second dielectric layer 208, the first dielectric layer 2060, and the ESL 204. Then a second patterned mask is formed and another dry etch process is performed to form a trench opening that overlaps with the via opening. The dry etches at block 112 may implement an oxygen-containing gas, hydrogen, a fluorine-containing gas (e.g., CF₄, SF₆, CH₂F₂, CHF₃, CH₃F, C₄H₈, C₄F₆, and/or C₂F₆), a carbon-containing gas (e.g., CO, CH₄, and/or C₃H₈), a chlorine-containing gas (e.g., Cl₂, CHCl₃, CCl₄, and/or BCl₃), a bromine-containing gas (e.g., HBr and/or CHBR₃), an iodine-containing gas, other suitable gases and/or plasmas, and/or combinations thereof. In some embodiments illustrated in FIG. 7, each of the contact openings 210 includes a via opening 210V and a line opening 210L over the via opening 210V.

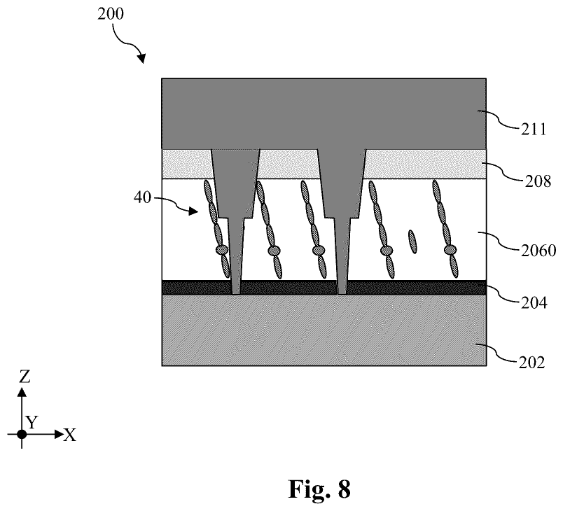

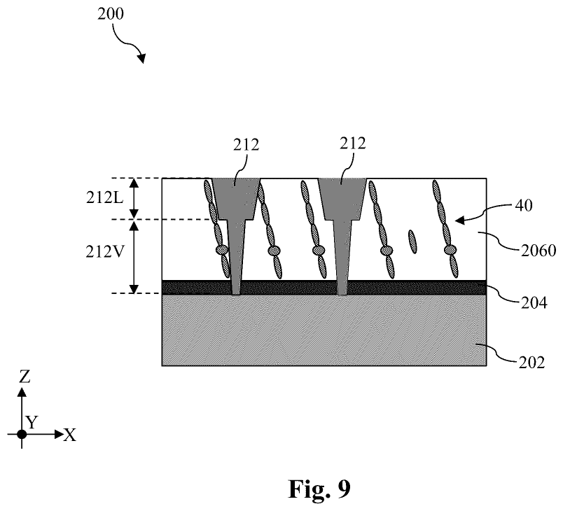

Referring to FIGS. 1, 8 and 9, method 100 includes a block 114 where contact features 212 are formed in the contact openings 210. Operations at block 114 may include deposition of a metal fill layer 211 over the contact openings 210 (shown in FIG. 8) and planarization of the workpiece 200 to remove excess materials (shown in FIG. 9). Referring to FIG. 8, the metal fill layer 211 may be deposited over the contact openings 210 using physical vapor deposition (PVD), electroplating, or electroless plating. In some embodiments, the metal fill layer 211 may include copper (Cu), cobalt (Co), nickel (Ni), ruthenium (Ru), or tungsten (W). In one embodiment, the metal fill layer 211 includes copper (Cu). As an example, the metal fill layer 211 may be deposited using electroplating. In this example process, a seed layer may be deposited over the workpiece 200 using PVD or CVD. The seed layer may include titanium, copper, or both. Then copper is deposited over the seed layer using electroplating. In some embodiments not explicitly shown in the figures, a barrier layer is deposited over the contact openings 210 before the deposition of the metal fill layer 211. In some instances, the barrier layer may include a metal nitride, such as titanium nitride, cobalt nitride, manganese nitride, nickel nitride, tungsten nitride, or tantalum nitride. In one embodiment, the barrier layer includes titanium nitride. The barrier layer may be deposited using CVD, plasma-enhanced CVD (PECVD), ALD, or plasma-enhanced ALD (PEALD). Referring to FIG. 9, after the deposition of the barrier layer and the metal fill layer 211, the workpiece 200 is planarized to expose the first dielectric layer 2060 to form the contact features 212. The planarization may include chemical mechanical polishing (CMP). As shown in FIG. 9, the workpiece 200 is planarized until a planar top surface of the workpiece 200 includes top surfaces of the first dielectric layer 2060 and the metal fill layer 211.

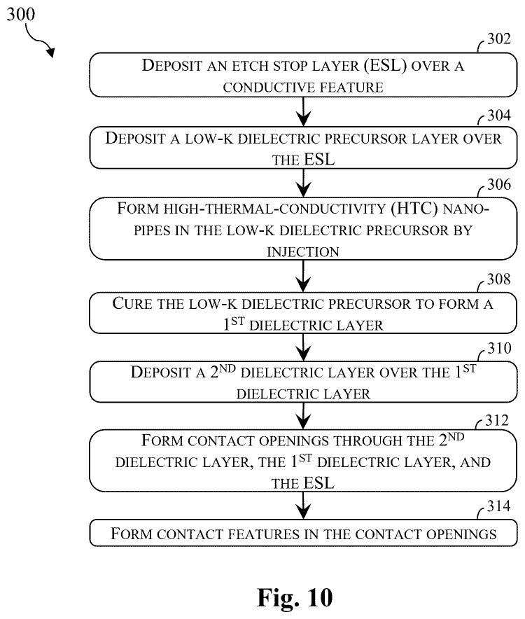

Method 100 forms nano-pipes 40 in the first dielectric layer 2060 by including high thermal conductivity nano-particles in a mixture 206, depositing the mixture 206 over a workpiece, and treating the mixture 206 to cause self-aggregation of the high thermal conductivity nano-particles before curing of the mixture 206, and curing of the mixture 206. Instead of depositing the mixture 206 over the workpiece, method 300 in FIG. 10 includes injecting high thermal conductivity nano-particles or nano-pipes into a low-k dielectric precursor layer deposited over a workpiece. Method 300 is described below in conjunction with fragmentary cross-sectional views of a workpiece 200 in FIGS. 11-19.

Referring to FIGS. 10 and 11, method 300 includes a block 302 where an etch stop layer (ESL) 204 is deposited over a conductive feature 202. Operations at block 302 are similar to those described above with respect to block 102. Detailed description of operations at block 302 is omitted for brevity.

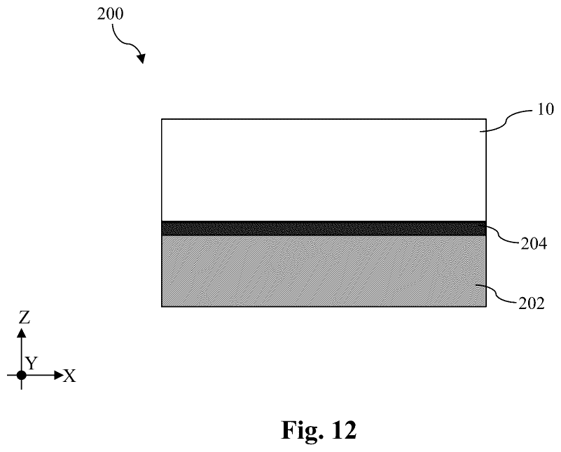

Referring to FIGS. 10 and 12, method 300 include a block 304 where a low-k dielectric precursor 10 is deposited over the ESL 204. In some embodiments, the low-k dielectric precursor 10 may include silicon (Si), carbon (C), oxygen (O), and hydrogen (H) and is suitable for spin-on coating or FCVD. In some embodiments, the low-k dielectric precursor 10 may include hydrogen-silsesquioxane (HSSQ), methyl-silsesquioxane (MSSQ), or carbon-doped silicon oxide (i.e., silicon-doped silica glass). In order for the subsequent injection step to be effective, the low-k dielectric precursor 10 is fluidic or flowable as deposited at block 304. The fluidity or flowability of the low-k dielectric precursor 10 allows nano-particles or nano-pipes to penetrate into the low-k dielectric precursor 10. At block 304, the low-k dielectric precursor 10 may be deposited over the ESL 204 by spin-on coating or FCVD.

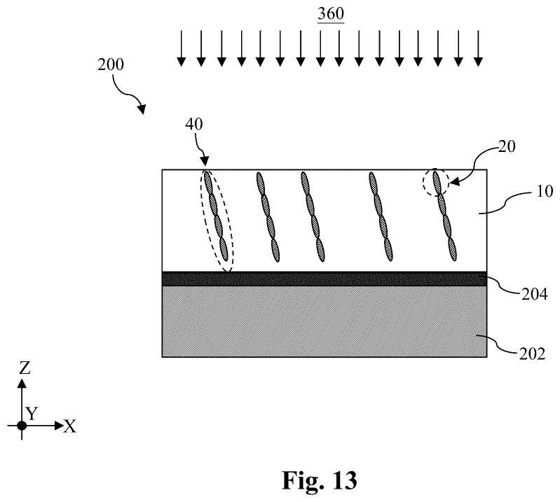

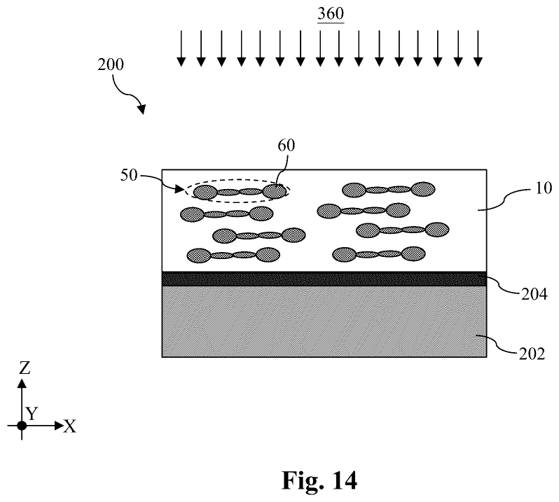

Referring to FIGS. 10, 13 and 14, method 300 includes a block 306 where high thermal conductivity nano-pipes 40 are formed in the low-k dielectric precursor 10. In some embodiments represented in FIGS. 13 and 14, the nano-pipes 40 are formed in the low-k dielectric precursor 10 by an injection process 360. In some embodiments, nano-particles, such as 1D nano-particles 20 and 2D nano-particles 30, are injected into the low-k dielectric precursor 10 deposited on the ESL 204. In these embodiments, the nano-particles is driven by pressure through a mold or a nozzle and the shear stress at the mold or nozzle cause the nano-particles to align along the direction of injection to form nano-pipes 40. In some other embodiments, nano-pipes 40 are pre-formed and dispersed in a suspension, a solution, or a sol-gel liquid and are injected into the low-k dielectric precursor 10 deposited on the ESL 204. Depending on the properties and shapes of the nano-particles, the nano-pipes formed by the injection process 360 may be perpendicular or horizontal to a top surface of the conductive feature 202. For example, in FIG. 13, when the nano-pipes 40 include 1D nano-particles 20, the nano-pipes 40 in the low-k dielectric precursor 10 may be aligned lengthwise along the Z direction as such an orientation presents the least resistance. Reference is then made to FIG. 14. When dumbbell-shape nano-pipes 50 with bulky end groups 60 are injected into the low-k dielectric precursor 10, resistance exerted on the bulky end groups 60 may cause the dumbbell-shaped nano-pipes 50 to have a horizontal orientation. The nano-pipes 40 or the dumbbell-shaped nano-pipes 50 may include carbon nanotubes (CNTs), boron nitride (BN), diamond, silicon carbide (SiC), beryllium oxide (BeO), boron phosphide (BP), aluminum nitride (AlN), beryllium sulfide (BeS), boron arsenide (BAs), gallium nitride (GaN), aluminum phosphide (AIP), gallium phosphide (GaP), or aluminum oxide (Al₂O₃).

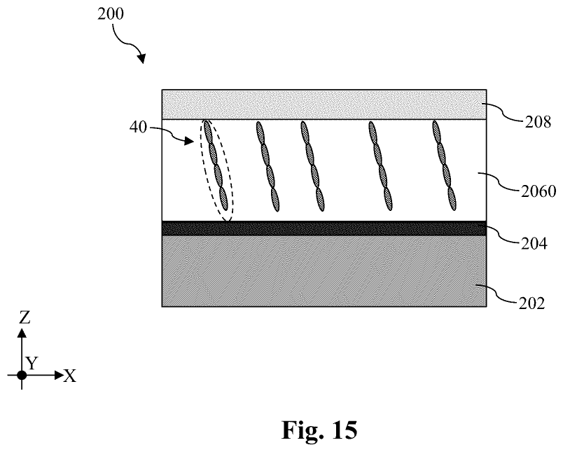

Referring to FIGS. 10 and 15, method 300 includes a block 308 where the low-k dielectric precursor 10 is cured to form a first dielectric layer 2060. Operations to cure the low-k dielectric precursor 10 at block 308 are similar to those described above with respect to curing of the mixture 206 at block 108. Detailed description of operations at block 308 is omitted for brevity.

Referring to FIGS. 10 and 15, method 300 includes a block 310 where a second dielectric layer 208 is deposited over the first dielectric layer 2060. Operations at block 310 are similar to those described above with respect to block 110. Detailed description of operations at block 310 is omitted for brevity.

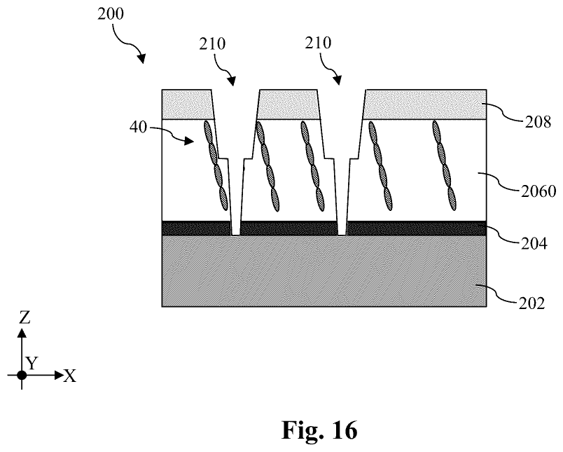

Referring to FIGS. 10 and 16, method 300 includes a block 312 where contact openings 210 are formed through the second dielectric layer 208, the first dielectric layer 2060, and the ESL 204. Operations at block 312 are similar to those described above with respect to block 112. Detailed description of operations at block 312 is omitted for brevity.

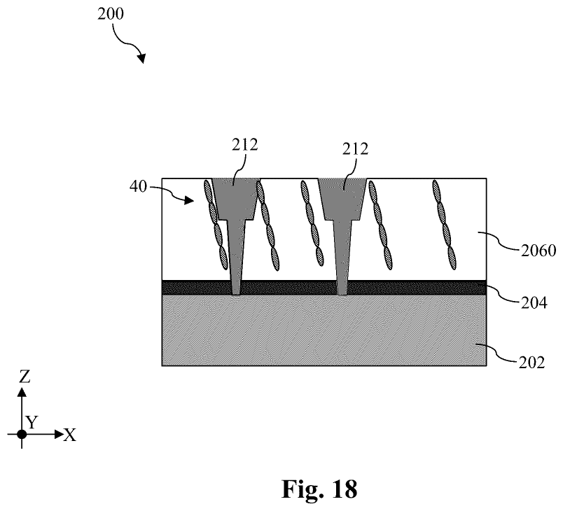

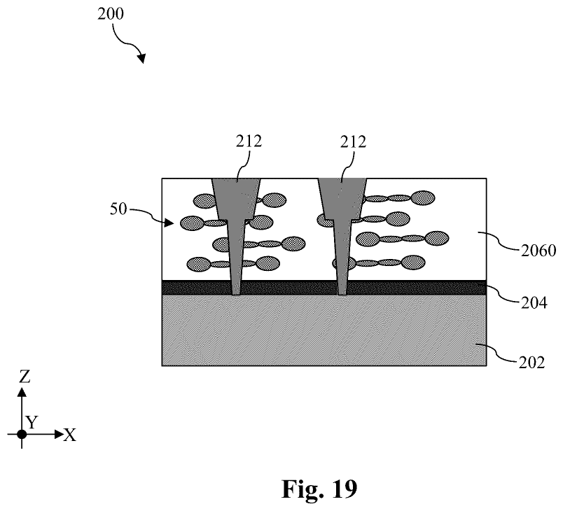

Referring to FIGS. 10 and 17-19, method 300 includes a block 314 where contact features 212 are formed in the contact openings 210. FIG. 18 illustrates contact features 212 extending through the first dielectric layer 2060 that includes vertically oriented nano-pipes 40. FIG. 19 illustrates contact features 212 extending through the first dielectric layer 2060 that includes horizontally oriented dumbbell-shaped nano-pipes 50. Operations at block 314 are similar to those described above with respect to block 114. Detailed description of operations at block 314 is omitted for brevity.

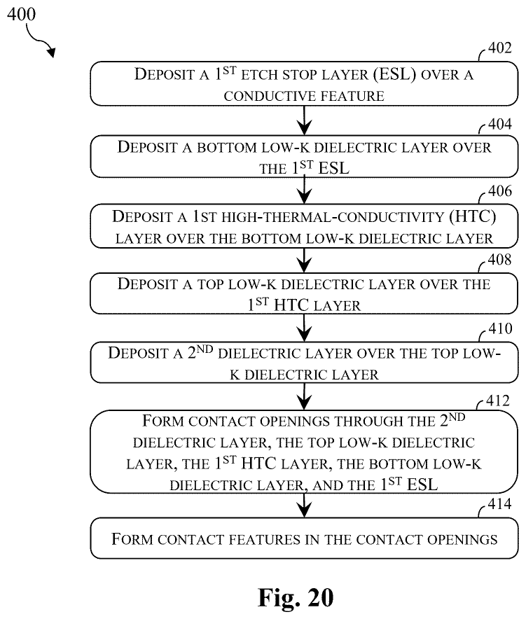

Instead of forming nano-pipes in a low-k dielectric layer, method 400 in FIG. 20 includes forming low-k dielectric layer and high thermal conductivity layers alternatingly to form a multilayer that has a low dielectric constant and provide directional heat dissipation.

Referring to FIGS. 20 and 21, method 400 includes a block 402 where an etch stop layer (ESL) 204 is deposited over a conductive feature 202. Operations at block 402 are similar to those described above with respect to block 102. Detailed description of operations at block 402 is omitted for brevity.

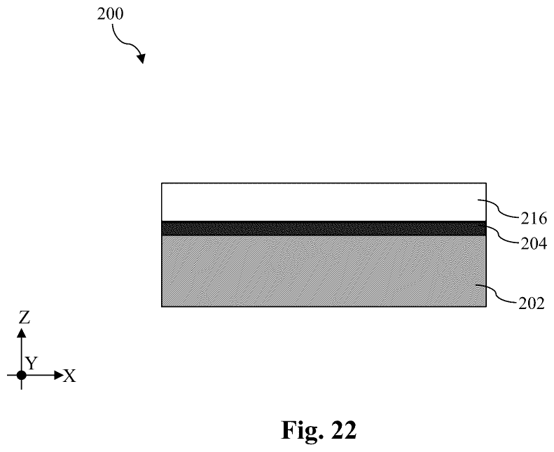

Referring to FIGS. 20 and 22, method 400 include a block 404 where a bottom low-k dielectric layer 216 is deposited over the ESL 204. In some embodiments, the deposition of the bottom low-k dielectric layer 216 includes deposition of a low-k dielectric precursor 10 over the ESL 204 and curing of low-k dielectric precursor 10. In some embodiments, the low-k dielectric precursor 10 may include silicon (Si), carbon (C), oxygen (O), and hydrogen (H). In some embodiments, the low-k dielectric precursor 10 may include hydrogen-silsesquioxane (HSSQ), methyl-silsesquioxane (MSSQ), or carbon-doped silicon oxide (i.e., silicon-doped silica glass). At block 404, the low-k dielectric precursor 10 may be deposited over the ESL 204 by spin-on coating or FCVD. The deposited low-k dielectric precursor 10 is then cured using an anneal process or a ultraviolet (UV) curing process. After curing, the bottom low-k dielectric layer 216 is formed.

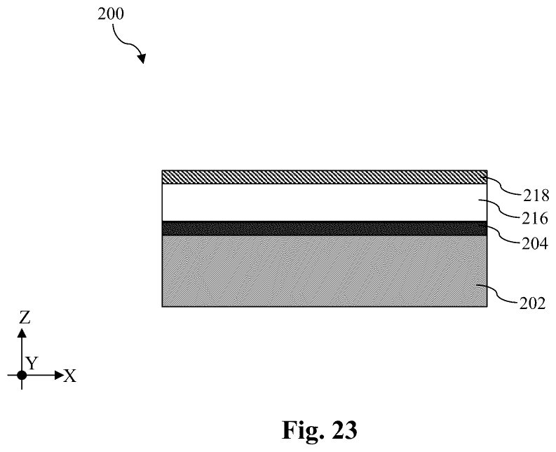

Referring to FIGS. 20 and 23, method 400 includes a block 406 where a first high thermal conductivity layer 218 is deposited over the bottom low-k dielectric layer 216. In some embodiments, the first high thermal conductivity layer 218 includes carbon nanotubes (CNTs), boron nitride (BN), diamond, silicon carbide (SIC), beryllium oxide (BeO), boron phosphide (BP), aluminum nitride (AlN), beryllium sulfide (BeS), boron arsenide (BAs), gallium nitride (GaN), aluminum phosphide (AIP), gallium phosphide (GaP), or aluminum oxide (Al₂O₃). In some implementations, the first high thermal conductivity layer 218 may be deposited using spin-on coating, PVD, CVD, FCVD, or ALD. For example, when the first high thermal conductivity layer 218 includes diamond, the first high thermal conductivity layer 218 may be deposited using spin-on coating. When the first high thermal conductivity layer 218 includes aluminum nitride (AlN) or silicon carbide (SiC), the first high thermal conductivity layer 218 may be deposited using CVD or PVD. When the first high thermal conductivity layer 218 is deposited using spin-on coating, a curing process such as an anneal process or a UV curing process may be needed to cure the first high thermal conductivity layer 218. When the first high thermal conductivity layer 218 is deposited using CVD, PVD, or ALD, no separate curing process may be needed.

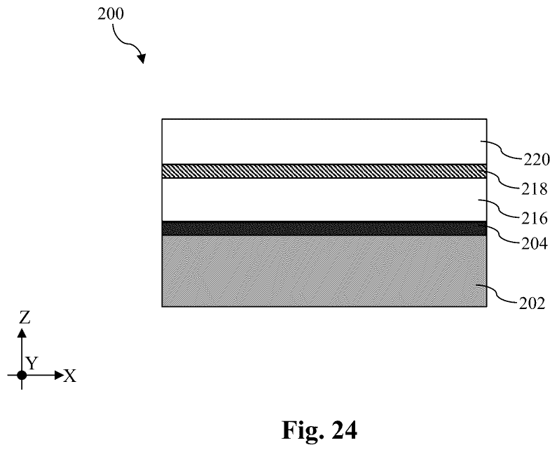

Referring to FIGS. 20 and 24, method 400 include a block 408 where a top low-k dielectric layer 220 is deposited over the first high thermal conductivity layer 218. In some embodiments, the top low-k dielectric layer 220 may be similar to the bottom low-k dielectric layer 216 in terms of both composition and the formation process. In some embodiments, the deposition of the top low-k dielectric layer 220 includes deposition of a low-k dielectric precursor 10 over the first high thermal conductivity layer 218 and curing of low-k dielectric precursor 10. In some embodiments, the low-k dielectric precursor 10 may include silicon (Si), carbon (C), oxygen (O), and hydrogen (H). In some embodiments, the low-k dielectric precursor 10 may include hydrogen-silsesquioxane (HSSQ), methyl-silsesquioxane (MSSQ), or carbon-doped silicon oxide (i.e., silicon-doped silica glass). At block 408, the low-k dielectric precursor 10 may be deposited over the first high thermal conductivity layer 218 by spin-on coating or FCVD. The deposited low-k dielectric precursor 10 is then cured using an anneal process or a ultraviolet (UV) curing process. After curing, the top low-k dielectric layer 220 is formed. At this point, the bottom low-k dielectric layer 216, the first high thermal conductivity layer 218, and the top low-k dielectric layer 220 form a first multilayer 230. Due to presence of the bottom low-k dielectric layer 216, the first high thermal conductivity layer 218, and the top low-k dielectric layer 220, the first multilayer 230 can dissipate heat efficiently horizontally when maintaining a relative low dielectric constant.

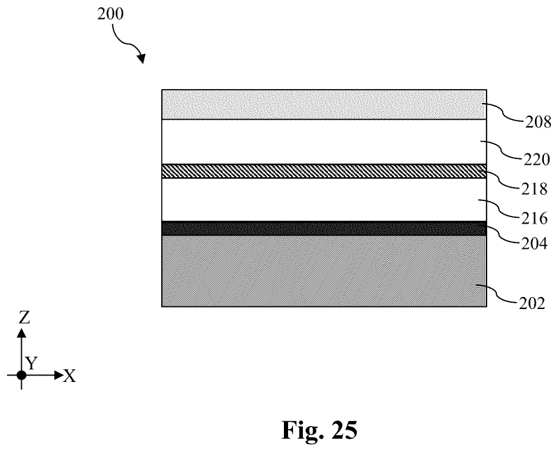

Referring to FIGS. 20 and 25, method 400 includes a block 410 where a second dielectric layer 208 is deposited over the first dielectric layer 2060. Operations at block 410 are similar to those described above with respect to block 110. Detailed description of operations at block 410 is omitted for brevity.

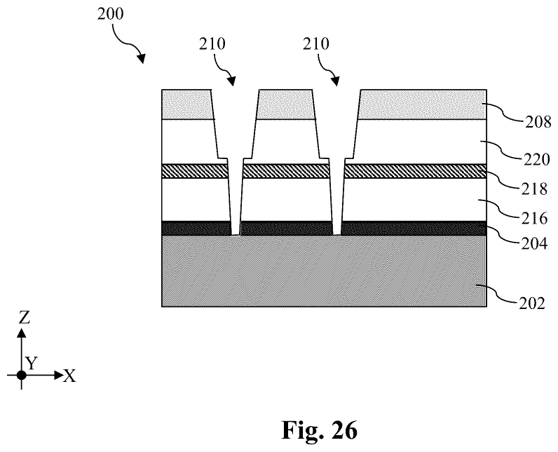

Referring to FIGS. 20 and 26, method 400 includes a block 412 where contact openings 210 are formed through the bottom low-k dielectric layer 216, the first dielectric layer 2060, and the ESL 204. Operations at block 412 are similar to those described above with respect to block 112. Detailed description of operations at block 412 is omitted for brevity. As shown in FIG. 26, the contact openings 210 extend through the second dielectric layer 208, the top low-k dielectric layer 220, the first high thermal conductivity layer 218, and a bottom low-k dielectric layer 216.

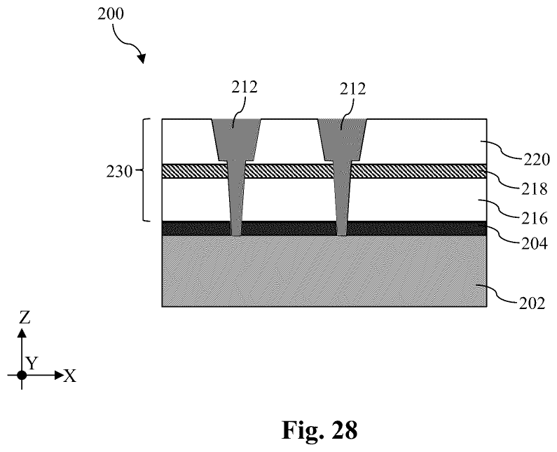

Referring to FIGS. 20, 27 and 28, method 400 includes a block 414 where contact features 212 are formed in the contact openings 210. Operations at block 414 are similar to those described above with respect to block 114. Detailed description of operations at block 414 is omitted for brevity. As shown in FIG. 28, the contact features 212 extend through the top low-k dielectric layer 220, the first high thermal conductivity layer 218, and the bottom low-k dielectric layer 216.

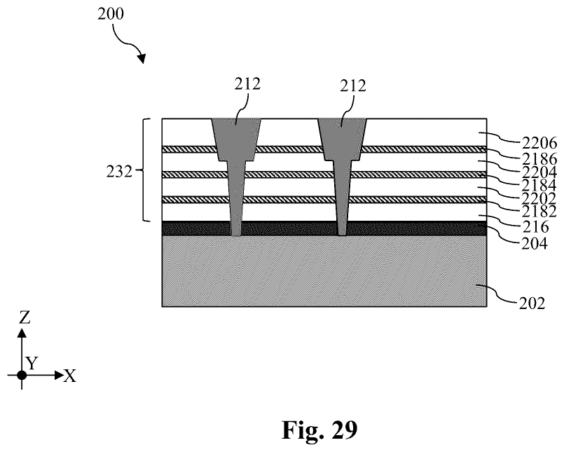

FIG. 29 illustrates an alternative embodiments where operations at block 406 and 408 are performed more than once to form a second multilayer 232. In the embodiments depicted in FIG. 29, the second multilayer 232 includes low-k dielectric layers 216, 2202, 2204, and 2206 that are interleaved by high thermal conductivity layers 2182, 2184, and 2186. Due to presence of the low-k dielectric layers and high thermal conductivity layers, the second multilayer 232 can dissipate heat efficiently horizontally when maintaining a relative low dielectric constant.

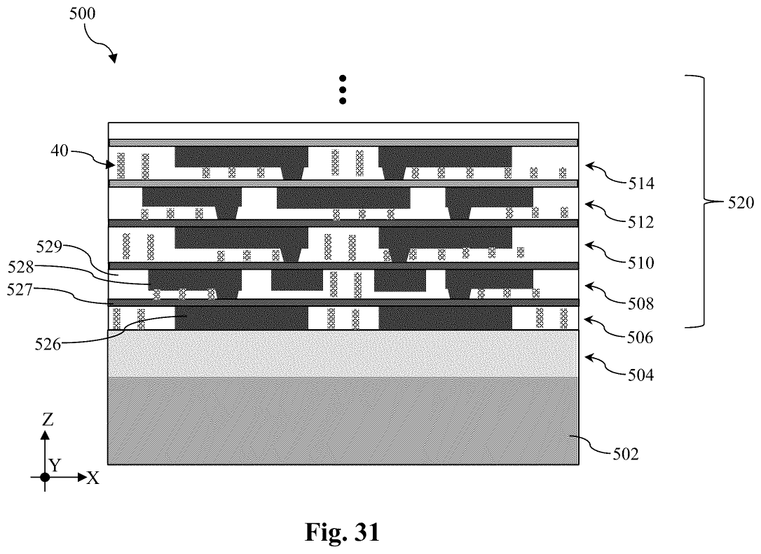

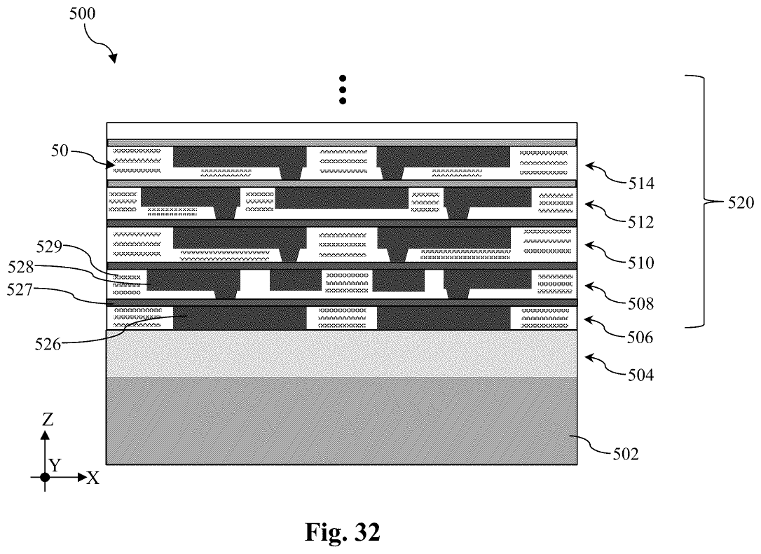

FIGS. 31 and 32 include schematic illustrations of implementation of low-k and high thermal conductivity structures of the present disclosure to a semiconductor device 500. The semiconductor device 500 includes a substrate 502, a device layer 504 over the substrate 502, and an interconnect layer 520 over the device layer 504. The substrate 502 may be a silicon (Si) substrate. In some other embodiments, the substrate 502 may include other semiconductors such as germanium (Ge), silicon germanium (SiGe), or a III-V semiconductor material. The substrate 502 may also include an insulating layer, such as a silicon oxide layer, to have a silicon-on-insulator (SOI) structure. The device layer 504 includes front-end-of-line (FEOL) structures fabricated on the substrate 502. The device layer 504 may include transistors, such as planar transistors, fin-type field effect transistors (FinFETs), gate-all-around (GAA) transistors, or complementary field effect transistors (CFETs). The interconnect structure 520 includes multiple metallization layers. In some implementations, the interconnect structure 520 includes between about 10 to about 20 metallization layers. In the embodiments depicted in FIGS. 31 and 32, the interconnect structure 520 includes a first metallization layer 506, a second metallization layer 508, a third metallization layer 510, a fourth metallization layer 512, and the fifth metallization layer 514. Additional metallization layers over the fifth metallization layer 514 are represented by dots. Each of the metallization layers includes contact features embedded in an intermetal dielectric (IMD) layer. For example, the second metallization layer 508 is disposed over an etch stop layer 527 and includes contact features 528 disposed in an IMD layer 529.

Reference is first made to FIG. 31. The nano-pipes 40, such as those shown in FIGS. 9 and 18, may be fabricated in each of the IMD layers in the interconnect structure 520. In the illustrated embodiment, a contact feature 526 in the first metallization layer 506 may correspond to the conductive feature 502 (shown in FIGS. 9 and 18), the etch stop layer 527 may correspond to the ESL 204 (shown in FIGS. 9 and 18), the IMD layer 528 may correspond to the first dielectric layer 2060. While the IMD layers in the interconnect structure 520 have a low dielectric constant to reduce parasitic capacitance, the nano-pipes 40 in the IMD layers provide vertical heat conduction paths to dissipate heat generated at the device layer 504 upward and away from the device layer 504.

Reference is first made to FIG. 32. The dumbbell-shape nano-pipes 50, such as those shown in FIG. 19, may be fabricated in each of the IMD layers in the interconnect structure 520. In the illustrated embodiment, a contact feature 526 in the first metallization layer 506 may correspond to the conductive feature 502 (shown in FIG. 19), the etch stop layer 527 may correspond to the ESL 204 (shown in FIG. 19), the IMD layer 528 may correspond to the first dielectric layer 2060. While the IMD layers in the interconnect structure 520 have a low dielectric constant to reduce parasitic capacitance, the dumbbell-shape nano-pipes 50 in the IMD layers provide horizontal heat conduction paths to evenly distribute heat along the horizontal plane (X-Y plane). Contact features in the interconnect structure 520 are connected to different devices in the device layer 504. Depending on whether the respective device generates heat, contact features may not be heated up uniformly. Additionally, some of the contact features may be dummy contact features to reduce loading effect and do not serve any circuit function. These dummy contact features may never heat up by the heat generated at the device layer 504. The horizontal heat conduction paths help evenly distribute heat among the contact features in each of the metallization layers. The IMD layers and the dumbbell-shape nano-pipes 50 shown in FIG. 32 may also be replaced by the first multilayer 230 in FIG. 28 or the second multilayer 232 in FIG. 29. Both the first multilayer 230 and the second multilayer 232 provide horizontal heat conduction paths by way of the high thermal conductivity layer(s).

Thus, one of the embodiments of the present disclosure provides a contact structure. The contact structure includes a conductive feature, an etch stop layer (ESL) over the conductive feature, a dielectric layer over the ESL, and a contact feature extending through the dielectric layer and the ESL to contact the conductive feature. The dielectric layer includes a low-k dielectric matrix material, and nano-pipes disposed in the low-k dielectric matrix material and configured to reduce a thermal resistance of the dielectric layer.

In some embodiments, each of the nano-pipes includes an elongated shape. In some implementations, the nano-pipes are aligned along a vertical direction. In some embodiments, each of the nano-pipes includes diamond, boron nitride, silicon carbide, beryllium oxide, boron phosphide, aluminum nitride, beryllium sulfide, boron arsenide, gallium nitride, aluminum phosphide, gallium phosphide, aluminum oxide, or graphene. In some embodiments, the low-k dielectric matrix material includes carbon-doped silica glass.

In another of the embodiments, a method is provided. The method includes depositing an etch stop layer (ESL) over a metal feature, depositing over the ESL a solution that includes a solvent, a low-k dielectric precursor, and at least one species of high thermal conductivity particles, treating the solution to cause self-aggregation of the at least one species of high thermal conductivity particles, curing the solution to form a low-k dielectric layer over the ESL, forming an opening through the low-k dielectric layer and the ESL, depositing a conductive material in the opening, and performing a planarization to expose a top surface of the low-k dielectric layer.

In some embodiments, the method of claim 6, wherein the at least one species of high thermal conductivity particles include diamond, boron nitride, silicon carbide, beryllium oxide, boron phosphide, aluminum nitride, beryllium sulfide, boron arsenide, gallium nitride, aluminum phosphide, gallium phosphide, aluminum oxide, or graphene. In some implementations, after the treating, the at least one species of high thermal conductivity particles are aligned to form nano-pipes. In some embodiments, the depositing of the solution includes spin-on coating or flowable chemical vapor deposition (FCVD). In some instances, the treating includes a first anneal process. In some embodiments, the treating further includes applying an electric field or a magnetic field. In some embodiments, the curing includes a second anneal process. The first anneal process includes a first anneal temperature and the second anneal process includes a second anneal temperature greater than the first anneal temperature. In some embodiments, the method further includes before the forming of the opening, depositing a hard mask dielectric layer over the low-k dielectric layer. The hard mask dielectric layer includes silicon oxide.

In yet another of the embodiments, a method is provided. The method includes depositing an etch stop layer (ESL) over a metal feature, forming a low-k dielectric layer over the ESL, wherein the low-k dielectric layer includes nano-pipes that are aligned along a direction, forming an opening through the low-k dielectric layer and the ESL, depositing a conductive material in the opening, and performing a planarization to expose a top surface of the low-k dielectric layer.

In some embodiments, the forming of the low-k dielectric layer includes depositing over the ESL a solution that includes a low-k dielectric precursor, and at least one species of high thermal conductivity particles, treating the solution to cause self-aggregation of the at least one species of high thermal conductivity particles to form the nano-pipes, and curing the solution to form a low-k dielectric layer over the ESL. In some instances, the at least one species of high thermal conductivity particles include diamond, boron nitride, silicon carbide, beryllium oxide, boron phosphide, aluminum nitride, beryllium sulfide, boron arsenide, gallium nitride, aluminum phosphide, gallium phosphide, aluminum oxide, or graphene. In some embodiments, the depositing of the solution includes spin-on coating or flowable chemical vapor deposition (FCVD). In some embodiments, the forming of the low-k dielectric layer includes depositing over the ESL a solution that includes a low-k dielectric precursor, and at least one species of high thermal conductivity particles, injecting the nano-pipes into the low-k dielectric precursor, and curing the low-k dielectric precursor. In some embodiments, the forming of the low-k dielectric layer includes depositing over the ESL a solution that includes a low-k dielectric precursor and at least one species of high thermal conductivity particles, injecting nano-particles into the low-k precursor through a nozzle to cause the at least one species of high thermal conductivity particles to form the nano-pipes, and curing the low-k dielectric precursor. In some embodiments, the direction is normal to a top surface of the metal feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A contact structure, comprising:
a conductive feature;
an etch stop layer (ESL) over the conductive feature;
a dielectric layer over the ESL; and
a contact feature extending through the dielectric layer and the ESL to contact the conductive feature,
wherein the dielectric layer comprises:
a low-k dielectric matrix material, and
nano-pipes disposed in the low-k dielectric matrix material and configured to reduce a thermal resistance of the dielectric layer.

2. The contact structure of claim 1, wherein each of the nano-pipes comprises an elongated shape.

3. The contact structure of claim 2, wherein the nano-pipes are aligned along a vertical direction.

4. The contact structure of claim 1, wherein each of the nano-pipes comprises diamond, boron nitride, silicon carbide, beryllium oxide, boron phosphide, aluminum nitride, beryllium sulfide, boron arsenide, gallium nitride, aluminum phosphide, gallium phosphide, aluminum oxide, or graphene.

5. The contact structure of claim 1, wherein the low-k dielectric matrix material comprises carbon-doped silica glass.

6. A method, comprising:
depositing an etch stop layer (ESL) over a metal feature;
depositing over the ESL a solution that includes:
a solvent,
a low-k dielectric precursor, and
at least one species of high thermal conductivity particles;
treating the solution to cause self-aggregation of the at least one species of high thermal conductivity particles;
curing the solution to form a low-k dielectric layer over the ESL;
forming an opening through the low-k dielectric layer and the ESL;
depositing a conductive material in the opening; and
performing a planarization to expose a top surface of the low-k dielectric layer.

7. The method of claim 6, wherein the at least one species of high thermal conductivity particles comprise diamond, boron nitride, silicon carbide, beryllium oxide, boron phosphide, aluminum nitride, beryllium sulfide, boron arsenide, gallium nitride, aluminum phosphide, gallium phosphide, aluminum oxide, or graphene.

8. The method of claim 6, wherein, after the treating, the at least one species of high thermal conductivity particles are aligned to form nano-pipes.

9. The method of claim 6, wherein the depositing of the solution comprises spin-on coating or flowable chemical vapor deposition (FCVD).

10. The method of claim 6, wherein the treating comprises a first anneal process.

11. The method of claim 10, wherein the treating further comprises applying an electric field or a magnetic field.

12. The method of claim 10,
wherein the curing comprises a second anneal process,
wherein the first anneal process comprises a first anneal temperature,
wherein the second anneal process comprises a second anneal temperature greater than the first anneal temperature.

13. The method of claim 6, further comprising:
before the forming of the opening, depositing a hard mask dielectric layer over the low-k dielectric layer,
wherein the hard mask dielectric layer comprises silicon oxide.

14. A method, comprising:
depositing an etch stop layer (ESL) over a metal feature;
forming a low-k dielectric layer over the ESL, wherein the low-k dielectric layer comprises nano-pipes that are aligned along a direction;
forming an opening through the low-k dielectric layer and the ESL;
depositing a conductive material in the opening; and
performing a planarization to expose a top surface of the low-k dielectric layer.

15. The method of claim 14, wherein the forming of the low-k dielectric layer comprises:
depositing over the ESL a solution that includes:
a low-k dielectric precursor, and
at least one species of high thermal conductivity particles;
treating the solution to cause self-aggregation of the at least one species of high thermal conductivity particles to form the nano-pipes; and
curing the solution to form a low-k dielectric layer over the ESL.

16. The method of claim 15, wherein the at least one species of high thermal conductivity particles comprise diamond, boron nitride, silicon carbide, beryllium oxide, boron phosphide, aluminum nitride, beryllium sulfide, boron arsenide, gallium nitride, aluminum phosphide, gallium phosphide, aluminum oxide, or graphene.

17. The method of claim 15, wherein the depositing of the solution comprises spin-on coating or flowable chemical vapor deposition (FCVD).

18. The method of claim 14, wherein the forming of the low-k dielectric layer comprises:
depositing over the ESL a solution that includes:
a low-k dielectric precursor, and
at least one species of high thermal conductivity particles;
injecting the nano-pipes into the low-k dielectric precursor; and
curing the low-k dielectric precursor.

19. The method of claim 14, wherein the forming of the low-k dielectric layer comprises:
depositing over the ESL a solution that includes:
a low-k dielectric precursor, and
at least one species of high thermal conductivity particles;
injecting nano-particles into the low-k precursor through a nozzle to cause the at least one species of high thermal conductivity particles to form the nano-pipes; and
curing the low-k dielectric precursor.

20. The method of claim 14, wherein the direction is normal to a top surface of the metal feature.
